(19) United States
(12) Patent Application Publication
(10) Pub. No.: US 2012/0133210 A1
(43) Pub. Date: May 31, 2012

(54) HYBRID ENERGY HARVESTER AND PORTABLE DEVICE THE SAME

(75) Inventors: Seungeon Moon, Daejeon (KR); Sang Kyun Lee, Gwangju (KR); Moon Gyu Jang, Daejeon (KR); Yil Suk Yang, Daejeon (KR); Jongdae Kim, Daejeon (KR)

(73) Assignee: ELECTRONICS AND TELECOMMUNICATIONS RESEARCH INSTITUTE, Daejeon (KR)

(21) Appl. No.: 13/242,914

(22) Filed: Sep. 23, 2011

(30) Foreign Application Priority Data
Nov. 30, 2010 (KR) 10-2010-0120638

(51) Int. Cl. H02J 1/00; H01L 35/28; H02N 2/18; H01L 35/02

(52) U.S. Cl. 307/80; 136/232; 136/224; 310/339

(57) ABSTRACT

Disclosed are a hybrid energy harvester and a portable device including the same. The hybrid energy harvester according to an exemplary embodiment of the present disclosure includes: a thermoelectric/piezoelectric element part that includes a thermoelectric element layer generating a voltage by a temperature difference, and a piezoelectric element layer generating a voltage by any one of vibration, pressure and force; an energy source selection part that selects a voltage generated in the thermoelectric element layer or the piezoelectric element layer; and a voltage controlling part that stores the voltage in an energy storage device by controlling the voltage selected in the energy source selection part.

### CROSS-REFERENCE TO RELATED APPLICATIONS

This application is based on and claims priority from Korean Patent Application No. 10-2010-0120638, filed on Nov. 30, 2010 with the Korean Intellectual Property Office, the disclosure of which is incorporated herein in its entirety by reference.

### TECHNICAL FIELD

The present disclosure relates to a hybrid energy harvester, and more particularly, to a hybrid energy harvester that stores electric energy in an energy storage device by converting an environmentally-friendly energy source including a temperature difference, vibration, and pressure caused by a touch/press of a hand of a man or the environment into electric energy, and a portable device including the same.

### BACKGROUND

A portable electronic device has relatively rapidly increased as compared to a non-portable electronic device because of the development of transportation means and globalization. As a representative matter thereof, there are a notebook, a cellular phone, an MP3 player, and a game machine.

Meanwhile, a rechargeable battery mainly used as an energy storage device does not yet satisfy a need of a user in terms of a capacity because of technical difficulty as compared to a development speed or an integration of a computer or a memory element. In order to solve this, various methods for charging the rechargeable battery once in order to use the battery as an electric source for the portable device for a long period of time while the size of the rechargeable battery is not increased, have been suggested.

As a representative matter thereof, charging methods of secondary batteries using sunlight, fuel and vibration have been studied, and in the case of a photovoltaic power generation, since the photovoltaic power generation is an environmentally-friendly energy source, a separate fuel supply is not required, but it is required that an expensive photovoltaic power generation module is provided at an external part of the portable device and always exposed to sunlight during electricity generation, such that there is a limit in design of the portable device and power generating efficiency is largely affected by sunlight.

In addition, the charging of the rechargeable battery using alcohol has an advantage in terms of cost or efficiency, but since a fossil fuel such as alcohol is inevitably used for charging, an additional device for converting the fossil fuel into electric energy is required.

### SUMMARY

The present disclosure has been made in an effort to provide a hybrid energy harvester that stores electric energy in an energy storage device by converting an environmentally-friendly energy source including a temperature difference, vibration, and pressure caused by a touch/press of a hand of a man or the environment into electric energy, and a portable device including the same.

An exemplary embodiment of the present disclosure provides a hybrid energy harvester, including: a thermoelectric/piezoelectric element part that includes a thermoelectric element layer generating a voltage by a temperature difference, and a piezoelectric element layer generating a voltage by any one of vibration, pressure and force; an energy source selection part that selects a voltage generated in the thermoelectric element layer or the piezoelectric element layer; and a voltage controlling part that stores the voltage in an energy storage device by controlling the voltage selected in the energy source selection part.

Another exemplary embodiment of the present disclosure provides a portable device including: a hybrid energy harvester including a thermoelectric/piezoelectric element part that includes a thermoelectric element layer generating a voltage by a temperature difference, and a piezoelectric element layer generating a voltage by any one of vibration, pressure and force; an energy source selection part that selects a voltage generated in the thermoelectric element layer or the piezoelectric element layer; and a voltage controlling part that stores the voltage in an energy storage device by controlling the voltage selected in the energy source selection part.

According to the exemplary embodiments of the present disclosure, it is possible to increase a using time of an energy storage device of a portable device and charge the energy storage device of the portable device even though there is no separate charging device in an emergency situation by providing a hybrid energy harvester that stores electric energy in the energy storage device by converting an environmentally-friendly energy source including a temperature difference, vibration, and pressure caused by a touch/press of a hand of a man or the environment into electric energy, and the portable device including the same.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block configuration view that schematically illustrates an internal configuration of a hybrid energy harvester according to an exemplary embodiment of the present disclosure.

FIG. 2 is a perspective view that illustrates a configuration of a thermoelectric/piezoelectric element part according to an exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings. The configuration of the present disclosure and operation effect thereof may be apparently understood through the following detailed description.

Before the detailed description of the present disclosure, like reference numerals are used for like and corresponding parts even though they are shown in different drawings, and in the case where it is judged that the known configuration may cloud the gist of the present disclosure, the detailed description thereof will be omitted.

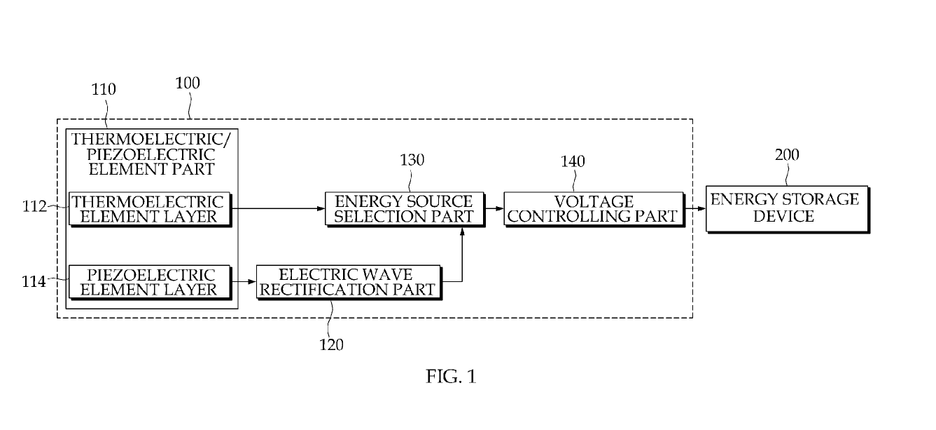

FIG. 1 is a block configuration view that schematically illustrates an internal configuration of a hybrid energy harvester according to an exemplary embodiment of the present disclosure.

Referring to FIG. 1, a hybrid energy harvester 100 according to the exemplary embodiment of the present disclosure includes a thermoelectric/piezoelectric element part 110 including a thermoelectric element layer 112 and a piezoelectric element layer 114, an electric wave rectification part 120, an energy source selection part 130 and a voltage controlling part 140.

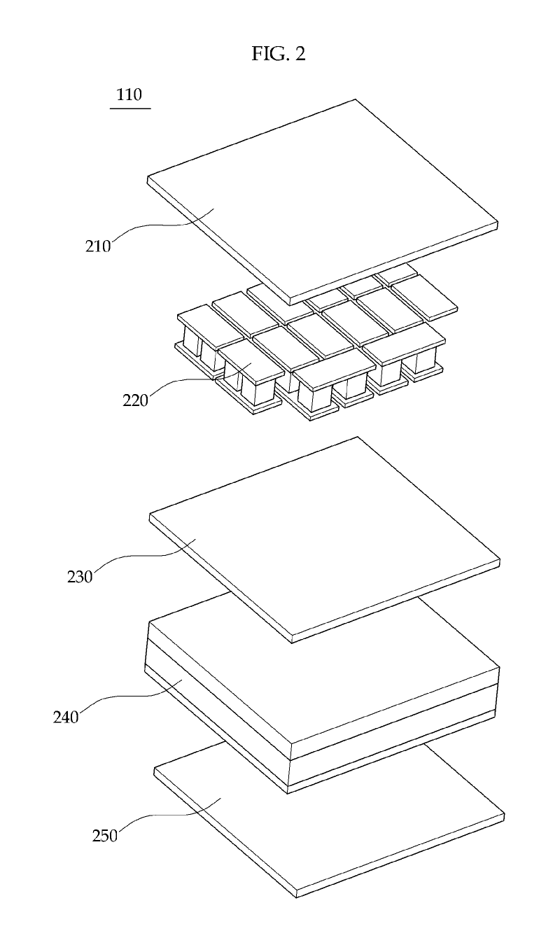

Thermoelectric/piezoelectric element part 110 is configured by multilayer including thermoelectric element layer 112 and piezoelectric element layer 114, thermoelectric element layer 112 generates a voltage by a temperature difference, and piezoelectric element layer 114 generates a voltage by vibration, pressure and force caused by a touch of a hand of a man or an environment. The detailed configuration of thermoelectric/piezoelectric element part 110 is illustrated in FIG. 2.

Electric wave rectification part 120 constantly maintains the voltage generated in piezoelectric element layer 114. The reason is that vibration, pressure and force applied from an external part thereof are not constant, such that the voltage generated in piezoelectric element layer 114 is not constant.

Energy source selection part 130 selects the voltage generated in thermoelectric element layer 112 or piezoelectric element layer 114. In this case, energy source selection part 130 selects the energy source having the larger voltage by comparing the voltage generated in thermoelectric element layer 112 and the voltage generated in piezoelectric element layer 114. In the exemplary embodiment of the present disclosure, hybrid energy harvester 100 is provided with energy source selection part 130 and selects the voltage generated in thermoelectric element layer 112 or piezoelectric element layer 114, but is not limited thereto, and hybrid energy harvester 100 may not be provided with energy source selection part 130 and store both of the voltages generated in thermoelectric element layer 112 and piezoelectric element layer 114 in energy storage device 200 of the portable device. Herein, the portable device may be various devices requiring charging, including a notebook, a cellular phone, an MP3 player, and a game machine.

Voltage controlling part 140 stores the voltage in energy storage device 200 of the portable device by controlling the voltage selected in energy source selection part 130. That is, voltage controlling part 140 converts the voltage selected in energy source selection part 130 into suitable voltage that can be stored in energy storage device 200 of the portable device.

FIG. 2 is a perspective view that illustrates a configuration of a thermoelectric/piezoelectric element part according to an exemplary embodiment of the present disclosure.

With reference to FIG. 2, thermoelectric/piezoelectric element part 110 according to the exemplary embodiment of the present disclosure includes a protective layer 210, a thermoelectric element layer 220, a first insulation layer 230, a piezoelectric element layer 240 and a second insulation layer 250 sequentially laminated. Herein, in the case where thermoelectric/piezoelectric element part 110 is made of transparent materials, thermoelectric/piezoelectric element part 110 may be inserted into a display device (not shown) of the portable device.

Protective layer 210 electrically insulates thermoelectric/piezoelectric element part 110 from an external part thereof and protects thermoelectric/piezoelectric element part 110 from contamination and breakage. Herein, protective layer 210 includes transparent polycarbonate, PET (polyethylene-terephthalate), PES (polyethersulfone), PI (polyimide), polynorbonene, PEN (polyethylenenapthelate), AryLite, quartz, glass, silicon (Si), gallium arsenic (GaAs) and indium phosphorus (InP).

Thermoelectric element layer 220 generates a voltage by a temperature difference. To this end, thermoelectric element layer 220 may be configured by a single or plural thermoelectric elements, and in the case where thermoelectric element layer 220 is configured by the plural thermoelectric elements, the thermoelectric elements may be electrically connected in series or in parallel. Herein, the single thermoelectric element includes a p-type semiconductor material and a n-type semiconductor material selected from silicon (Si), (Bi₂(Te,Se)₃, (Bi,Sb)₂Te₃, Zn₄Sb₃, (Pb,Sn)Te, Ca₃CO₄O₉, (Zn,Al)O, (Ba,Sr)Pb, (ZnO)mIn₂O₃, SrTiO₃, CaMnO₃, (Li,Ni)O, NaxCO₂O₄, La(Mn,M)O₃ and LaFe₃CoSb₁₂, and the selected p-type semiconductor material and n-type semiconductor material are connected through an electrode (not shown). Herein, the electrode (not shown) includes metals, conducting metal oxides, and conducting polymers, for example, silver, gold, platinum, copper, aluminum, rhodium, iridium, ruthenium, palladium, In—Ga—Zn—O, SrRuO₃, (La,Sr)CoO₃ and Sr(Nb,Ti)O₃, polyacetylene, polyaniline, polypyrrole, polythiopene, etc.

First insulation layer 230 electrically and thermally insulates thermoelectric element layer 220 and piezoelectric element layer 240 from each other. Herein, first insulation layer 230 includes transparent polycarbonate, PET (polyethylene-terephthalate), PES (polyethersulfone), PI (polyimide), polynorbonene, PEN (polyethylenenapthelate), AryLite, quartz, glass, silicon (Si), gallium arsenic (GaAs) and indium phosphorus (InP).

Piezoelectric element layer 240 generates a voltage by vibration, pressure, and force. To this end, piezoelectric element layer 240 may be configured by a single or plural piezoelectric elements, and in the case where piezoelectric element layer 240 is configured by the plural piezoelectric elements, the piezoelectric elements may be electrically connected in series or in parallel. Herein, in the single piezoelectric element includes materials of quartz, Rochelle salt, (Na,Ca)(Mg,Fe)₃B₃Al₆Si₆(O,OH,F)₃₁, GaPO₄, Ca₃Ga₂Ge₄O₁₄, LiNbO₃, LiTaO₃, Li₂B₄O₇, Li₂SO₄H₂O, Bi₁₂GeO₂₀, Bi₁₂SiO₂₀, SbSI, aluminum nitride (AlN), zinc oxide (ZnO), PZT(Pb(Zr,Ti)O₃), tungsten bronze, a Perovskite layer structure, BST((Ba,Sr)TiO₃), NkN((Na,K)NbO₃), bismuth titanate, carbon nanotube (CNT), polyvinylidenefluoride (PVDF) and polypropylene-polyethylene (PE-PP), and the electrode (not shown) is formed at a left part and a right part or an upper part and a lower part of the material. Herein, the electrode (not shown) includes metals, conducting metal oxides, and conducting polymers, for example, silver, gold, platinum, copper, aluminum, rhodium, iridium, ruthenium, palladium, In—Ga—Zn—O, SrRuO₃, (La,Sr)CoO₃ and Sr(Nb,Ti)O₃, polyacetylene, polyaniline, polypyrrole, polythiopene, etc.

Second insulation layer 250 electrically insulates the thermoelectric/piezoelectric element part 110 and a lower structure. This minimizes an electric interference to an internal device of the portable device in the case where thermoelectric/piezoelectric element part 110 is inserted into the internal part of the portable device. To this end, second insulation layer 250 includes transparent polycarbonate, PET (polyethylene-terephthalate), PES (polyethersulfone), PI (polyimide), polynorbonene, PEN (polyethylenenapthelate), AryLite, quartz, glass, silicon (Si), gallium arsenic (GaAs) and indium phosphorus (InP) like first insulation layer 230.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A hybrid energy harvester, comprising:
a thermoelectric/piezoelectric element part that includes a thermoelectric element layer generating a voltage by a temperature difference, and a piezoelectric element layer generating a voltage by any one of vibration, pressure and force;
an energy source selection part that selects a voltage generated in the thermoelectric element layer or the piezoelectric element layer; and
a voltage controlling part that stores the voltage in an energy storage device by controlling the voltage selected in the energy source selection part.

2. The hybrid energy harvester of claim 1, wherein the thermoelectric/piezoelectric element part further comprises:
a protective layer that electrically insulates the thermoelectric/piezoelectric element part and protects the thermoelectric/piezoelectric element part from contamination and breakage;
a first insulation layer that electrically and thermally insulates the thermoelectric element layer and the piezoelectric element layer from each other; and
a second insulation layer that electrically insulates the thermoelectric/piezoelectric element part from a lower structure.

3. The hybrid energy harvester of claim 2, wherein the protective layer includes at least one of transparent polycarbonate, PET (polyethylene-terephthalate), PES (polyethersulfone), PI (polyimide), polynorbonene, PEN (polyethylenenapthelate), AryLite, quartz, glass, silicon (Si), gallium arsenic (GaAs) and indium phosphorus (InP).

4. The hybrid energy harvester of claim 2, wherein each of the first insulation layer and the second insulation layer includes at least one of transparent polycarbonate, PET (polyethylene-terephthalate), PES (polyethersulfone), PI (polyimide), polynorbonene, PEN (polyethylenenapthelate), AryLite, quartz, glass, silicon (Si), gallium arsenic (GaAs) and indium phosphorus (InP).

5. The hybrid energy harvester of claim 1, wherein the thermoelectric element layer is configured by a single or plural thermoelectric elements.

6. The hybrid energy harvester of claim 5, wherein in the case where the thermoelectric element layer is configured by a plurality of thermoelectric elements, the thermoelectric elements electrically connected in series or in parallel.

7. The hybrid energy harvester of claim 5, wherein the single thermoelectric element includes a p-type semiconductor material and a n-type semiconductor material selected from silicon (Si), (Bi₂(Te,Se)₃, (Bi,Sb)₂Te₃, Zn₄Sb₃, (Pb,Sn)Te, Ca₃CO₄O₉, (Zn,Al)O, (Ba,Sr)Pb, (ZnO)mIn₂O₃, SrTiO₃, CaMnO₃, (Li,Ni)O, NaxCO₂O₄, La(Mn,M)O₃ and LaFe₃CoSb₁₂, and the selected p-type semiconductor material and n-type semiconductor material are connected through an electrode.

8. The hybrid energy harvester of claim 7, wherein the electrode includes at least one of metals, conducting metal oxides, and conducting polymers(silver, gold, platinum, copper, aluminum, rhodium, iridium, ruthenium, palladium, In—Ga—Zn—O, SrRuO₃, (La,Sr)CoO₃ and Sr(Nb,Ti)O₃, polyacetylene, polyaniline, polypyrrole, polythiopene).

9. The hybrid energy harvester of claim 1, wherein the piezoelectric element layer is configured by a single or plural piezoelectric elements.

10. The hybrid energy harvester of claim 9, wherein in the case where the piezoelectric element layer is configured by a plurality of piezoelectric elements, the piezoelectric elements electrically connected in series or in parallel.

11. The hybrid energy harvester of claim 9, wherein the single piezoelectric element includes any one of quartz, Rochelle salt, (Na,Ca)(Mg,Fe)₃B₃Al₆Si₆(O,OH,F)₃₁, GaPO₄, Ca₃Ga₂Ge₄O₁₄, LiNbO₃, LiTaO₃, Li₂B₄O₇, Li₂SO₄H₂O, Bi₁₂GeO₂₀, Bi₁₂SiO₂₀, SbSI, aluminum nitride (AlN), zinc oxide (ZnO), PZT(Pb(Zr,Ti)O₃), tungsten bronze, a Perovskite layer structure, BST((Ba,Sr)TiO₃), NkN((Na,K)NbO₃), bismuth titanate, carbon nanotube (CNT), polyvinylidenefluoride (PVDF) and polypropylene-polyethylene (PE-PP), and the electrode is formed at a left part and a right part or an upper part and a lower part of the material.

12. The hybrid energy harvester of claim 11, wherein the electrode includes at least one of metals, conducting metal oxides, and conducting polymers(silver, gold, platinum, copper, aluminum, rhodium, iridium, ruthenium, palladium, In—Ga—Zn—O, SrRuO₃, (La,Sr)CoO₃ and Sr(Nb,Ti)O₃, polyacetylene, polyaniline, polypyrrole, polythiopene).

13. The hybrid energy harvester of claim 1, further comprising:
an electric wave rectification part that constantly maintains a voltage generated in the piezoelectric element layer.

14. A portable device, comprising:
a hybrid energy harvester including:
a thermoelectric/piezoelectric element part that includes a thermoelectric element layer generating a voltage by a temperature difference, and a piezoelectric element layer generating a voltage by any one of vibration, pressure and force;
an energy source selection part that selects the voltage generated in the thermoelectric element layer or the piezoelectric element layer; and
a voltage controlling part that stores the voltage in an energy storage device by controlling the voltage selected in the energy source selection part.

15. The device of claim 14, wherein the thermoelectric/piezoelectric element part is inserted into a display device of the portable device.

16. The device of claim 14, wherein the portable device is any one of a notebook, a cellular phone, an MP3 player, and a game machine.
